(19) United States
(12) Patent Application Publication
(10) Pub. No.: US 2005/0104196 A1
(43) Pub. Date: May 19, 2005

(54) Semiconductor package

(75) Inventor: Atsushi Kashiwazaki, Anjo-city (JP)

Correspondence Address: POSZ LAW GROUP, PLC, 11250 ROGER BACON DRIVE, SUITE 10, RESTON, VA, 20190, US

(73) Assignee: DENSO CORPORATION

(21) Appl. No.: 10/974,727

(22) Filed: Oct. 28, 2004

(30) Foreign Application Priority Data
Nov. 18, 2003 (JP) 2003-388107
Jul. 21, 2004 (JP) 2004-213466

(51) Int. Cl. H01L 23/02

(52) U.S. Cl. 257/706

(57) ABSTRACT

A semiconductor package includes interposer substrates for providing miniaturization. One side of a first interposer substrate having a through-hole is fixed to one side of a heat sink. A non-active side of a semiconductor chip is fixed on one side of the heat sink in the through-hole of the first interposer substrate. The semiconductor chip and the first interposer substrate are connected electrically by bonding wire. One side of a second interposer substrate is fixed on the active side of the semiconductor chip that is located inside of the through-hole of the first interposer substrate. The semiconductor chip and the second interposer substrate are connected electrically by bonding wire.

### CROSS REFERENCE TO RELATED APPLICATIONS

This application is based upon, claims the benefit of priority of, and incorporates by reference the contents of Japanese Patent Application No. 2003-388107 filed on Nov. 18, 2003 and Japanese Patent Application No. 2004-213466 filed on Jul. 21, 2004.

### FIELD OF THE INVENTION

The present invention relates to a semiconductor package that includes a semiconductor chip and an interposer substrate electrically connected with a wire bonding.

### BACKGROUND OF THE INVENTION

Referring to FIG. 16, a related art semiconductor package including an interposer substrate that satisfies heat dissipation efficiency requirements will be discussed. The package includes a heat sink 100 and an interposer substrate 101 attached to one side of the heat sink 100. The interposer substrate 101 includes a through-hole 101a. A semiconductor chip 102 is attached to the heat sink 100 in the through-hole 101A in the interposer substrate 101. More particularly, the semiconductor chip 102 is enclosed in the through-hole 101A in the interposer substrate 101. The semiconductor chip 102 and the interposer substrate 101 are electrically connected by gold bonding wire 103. There are bonding electrodes 104 for gold bonding wires and other electrodes (pads 105) used for a connection with a mother board 107 on the interposer substrate 101, and solder balls 106 are disposed on the electrodes (pads 105). The through hold 101A will be sealed by resin 108 in order to protect the gold bonding wires 103.

Referring to FIG. 17, a related art semiconductor package for a heat dissipating element that does not require a heat sink will be discussed. The package includes an interposer substrate 110 having a cavity (a concave portion) 11, and a semiconductor chip 111 that is attached to the bottom of the cavity and thereby enclosed by the cavity. On the other side of the interposer substrate 110 (opposite side to the one that carries the semiconductor chip 111), an electric component 112 is surface-mounted onto the substrate. By adopting this type of structure, a whole substrate product can be miniaturized.

However, connecting electrodes that are connected to a motherboard 107 can only be disposed on the interposer substrates 101 and 110 in the semiconductor package shown in FIGS. 16 and 17. As a result, the entire surface under the semiconductor package cannot be used for a connection to the mother board 107, and efficient miniaturization of the package cannot be achieved. Further, when the chip has a large number of output terminals in comparison to the chip size, miniaturization efficiency of is further worsened.

### SUMMARY OF THE INVENTION

In view of the foregoing problems, the present disclosure concerns a semiconductor package that is miniaturized by using an interposer substrate.

According to a first aspect, a semiconductor package with a structure where one side of a first interposer substrate has a through-hole fixed to one side of a heat sink, a non-active side of a semiconductor chip is fixed to one side of the heat sink in the through-hole, and the semiconductor chip and the first interposer substrate are electrically connected by bonding wires wherein one side of a second interposer substrate is fixed on an active side of the semiconductor chip at an inside of the through-hole of the first interposer substrate, and the semiconductor chip and the second interposer substrate are electrically connected by the bonding wires. Accordingly, miniaturization of a semiconductor package by forming electrodes for the connection to the mother board even on the second interposer substrate on the active side of a semiconductor chip is enabled.

According to a second aspect, the semiconductor package according to the first aspect has a plurality of semiconductor chips arranged in a stacked layer structure, and each chip in the stacked layer structure is arranged so that its active side is opposed to the non-active side of the other chip. The package has a connection structure in which at least one of the chips in the stacked layer structure and the first interposer substrate, and another chip in the stacked layer structure and the second interposer substrate are electrically connected by the bonding wires. This structure is favorable for miniaturization when multiple chips are arranged in a layered stack.

According to a third aspect, a non-active side of a semiconductor chip is fixed at the bottom of a concave portion of the first interposer substrate. The semiconductor chip and the first interposer substrate are electrically connected by bonding wires. In this package, one side of the second interposer substrate is fixed to the active side of the semiconductor chip. The semiconductor chip and the second interposer substrate are connected by bonding wires. A semiconductor package according to the third aspect enables miniaturization of a by forming electrodes for the connection to the mother board even on the second interposer substrate on the active side of a semiconductor chip.

According to a fourth aspect, the semiconductor package according to the third aspect has a plurality of semiconductor chips arranged in a stacked layer structure, and each chip in the stacked layer structure has an arrangement of its active side opposed to the non-active side of the other chip. The package has a connection structure in which one of the chips in the stacked layer structure and the first interposer substrate, and another chip in the stacked layer structure and the second interposer substrate are electrically connected by the bonding wires. This structure is favorable in the stacked chip layering structure when miniaturization is pursued.

According to a fifth aspect, the semiconductor package according to the third or fourth aspect, has an electronic component being implemented on the opposite side of the first interposer substrate, and the substrate has the semiconductor chip disposed on another side. Electric components disposed on the back side of a semiconductor chip rather than on the mother board permit miniaturization of the mother board.

According to a sixth aspect, the semiconductor package according to claim the third or fourth aspect, has another semiconductor chip being Implemented on the opposite side of the first interposer substrate, and the substrate has the semiconductor chip disposed on another side. Mounting the semiconductor chip on the back of the semiconductor package rather than on the mother board permits miniaturization of the mother board.

According to a seventh aspect, the semiconductor package according to any one of the first to fourth aspects, has step portions being disposed on an electrode side of the first and second interposer substrates, and an electrode to be bonded to the bonding wires is disposed on the step portion. This structure favors miniaturization of the semiconductor package by limiting the overflow of resin for protecting bonding wires and suppressing the distance between the bonding electrodes and the connecting-to-the-mother-board electrodes. By adopting this structure, the height of the resin can be set under the surface of the interposer substrate, and manufacturing cost can be reduced by eliminating solder balls on the electrodes.

According to an eighth aspect, the semiconductor package according to any one of the first to fourth aspects, further has the semiconductor chip and the second interposer substrate in a flip-chip type of connection with an interfacing bump. By adopting this structure, the semiconductor chip that has electrodes arranged not only on the periphery but also on the inner area of the package can effectively be miniaturized in the same regards as the first to fourth aspects.

According to a ninth aspect, the semiconductor package according to any one of the first to fourth aspects has an interval of the electrodes disposed on the second interposer substrate for the connection to the mother board being different from an interval of the electrodes disposed on the first interposer substrate for the connection to the mother board. This structure favors miniaturization of the semiconductor package by decreasing the interval of the electrodes on the second interposer substrate and thus increasing the number of the electrodes on the second interposer substrate, and as a result decreasing the number of the electrodes on the first interposer substrate.

According to a tenth aspect, the semiconductor package according to any one of the first to fourth aspects, has a height of the surface on the second interposer substrate that carries the electrodes to be connected electrically and mechanically to the mother board. The height is different from the height of the surface on the first interposer substrate that carries the electrodes to be connected to the mother board. The first and second interposer substrates are connected electrically and mechanically to the mother board by conductive material such as solder and silver paste. As described above regarding the ninth aspect, the sizes of the electrodes are different because of the difference of the interval distance. This leads to the difference of the amount of the conductive material used for connecting the interposer substrate to the mother board. By changing the first interposer substrate and the second interposer substrate, the gap between the substrates can be adjusted to the suitable one for the amount of the resin.

According to an eleventh aspect, the semiconductor package according to any one of the first to fourth aspects, has a different material for the first interposer substrate and for the second interposer substrate. The mother board and the semiconductor package are connected by the conductive material such as solder and the like. However, the difference of the linear expansion coefficient between the mother board and the semiconductor package causes stress at connection points. Repeated expansion results in the breakage of connection points and thus causes malfunction. This kind of thermal stress caused by the difference of linear expansion coefficient increases proportionally to the distance from the center of the electrodes area. Therefore, the material for the first interposer substrate should have a linear expansion coefficient similar that of the mother board. Moreover, although the second interposer substrate has a limitation in size based of the size of the semiconductor chip, the semiconductor package can be further miniaturized if electrodes were disposed on the second interposer substrate. Thus, the second interposer substrate uses a special substrate that can accommodate a high density circuit. By carefully choosing the material for the substrates, the semiconductor package can strike a balance between size of the package and the manufacturing cost.

### BRIEF DESCRIPTION OF THE DRAWINGS

The above and other objects, features and advantages of the present invention will become more apparent from the following detailed description made with reference to the accompanying drawings:

FIG. 1 shows a vertical cross section of a semiconductor package according to a first embodiment;

FIG. 2A shows a bottom view of a semiconductor package, FIG. 2B is an enlarged view of a portion of FIG. 2A;

FIG. 3 shows a vertical cross section of a semiconductor package according to a second embodiment;

FIG. 4 shows a vertical cross section of a semiconductor package;

FIG. 5 shows a vertical cross section of a semiconductor package;

FIG. 6 shows a vertical cross section of a semiconductor package according to a third embodiment;

FIG. 7 shows a vertical cross section of a semiconductor package according to a fourth embodiment;

FIG. 8 shows a vertical cross section of a semiconductor package according to a fifth embodiment;

FIG. 9 shows a vertical cross section of a semiconductor package according to a sixth embodiment;

FIG. 10A shows a bottom view of a semiconductor package, FIG. 10B shows an enlarged view of a portion of FIG. 10A;

FIG. 11 shows a vertical cross section of a semiconductor package;

FIG. 12 shows a vertical cross section of a semiconductor package;

FIG. 13 shows a vertical cross section of a semiconductor package;

FIG. 14 shows a vertical cross section of a semiconductor package;

FIG. 15 shows a vertical cross section of a semiconductor package for an exemplary comparison;

FIG. 16 shows a vertical cross section of a related art semiconductor package; and

FIG. 17 shows a vertical cross section of a related art semiconductor package.

### DETAILED DESCRIPTION OF THE PREFERRED EMBODIMENTS

(First Embodiment)

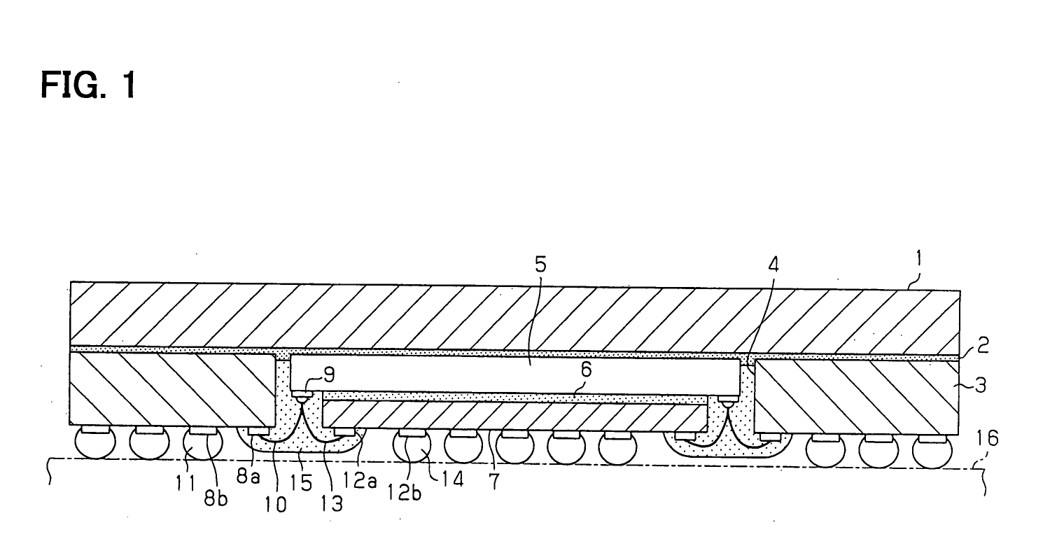

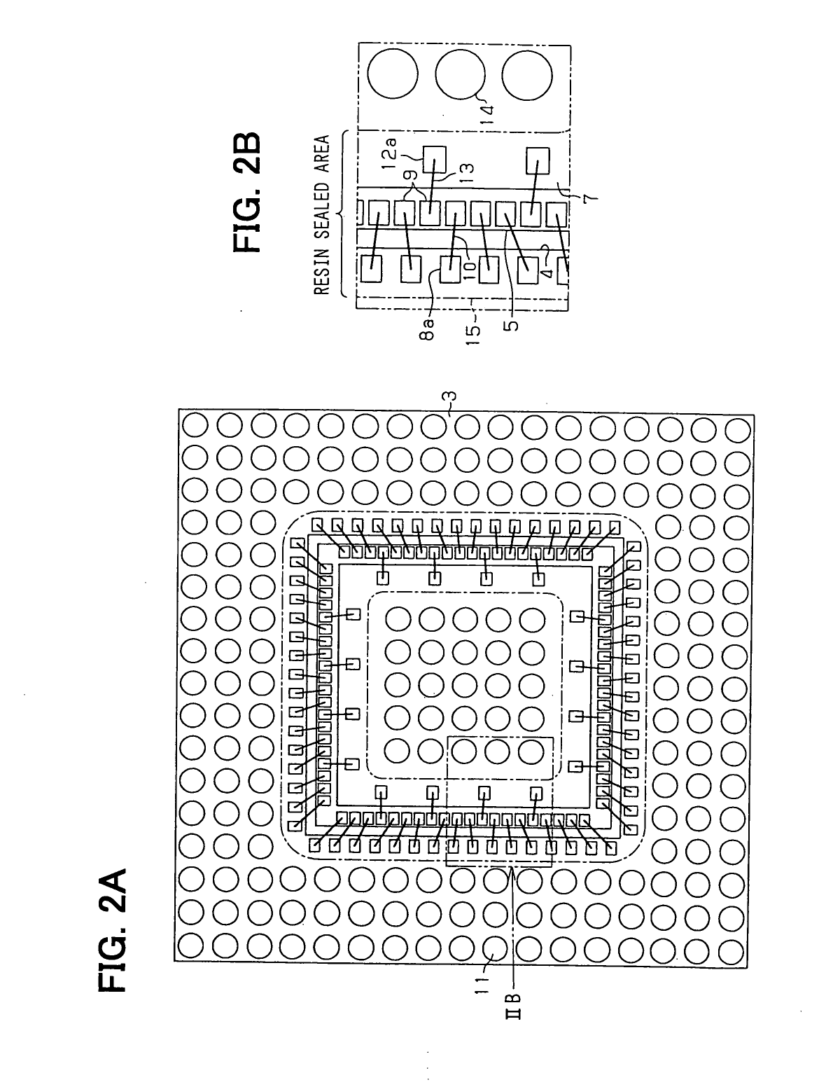

A preferred first embodiment of the present invention will be described here with reference to the drawings. FIG. 1 shows a vertical section of the semiconductor package in this embodiment. FIG. 2 shows a lower surface of the semiconductor package in this embodiment (Planar diagram of the surface that opposes to the mother board 16 in FIG. 1).

The semiconductor package includes a heat sink 1 having a rectangular board shape. A first interposer substrate 3 is fixed to a lower surface of the heat sink 1 by an adhesive 2. The first interposer substrate 3 has a through-hole 4 in the center. A non-active side of a semiconductor chip 5 is fixed to one side (lower side) of the heat sink 1 inside of the through-hole 4 by using the adhesive 2 to thereby enclose the semiconductor chip 5 in the through-hole 4. Further, in the center of the active side (lower surface) of the semiconductor chip 5 that exists in the through-hole 4, one side of the second interposer substrate 7 is fixed by using an adhesive 6. In a broader sense, one side of the second interposer substrate 7 is fixed to the active side of the semiconductor chip 5. The second interposer substrate 7 is smaller than the semiconductor chip 5, and there are a large number of bonding pads (electrodes) 9 formed in the vacant area that is not covered by the second interposer substrate 7 (periphery) on the active side (lower surface) of the semiconductor chip 5.

A large number of bonding pads (electrodes) 8A are formed on the lower surface of the first interposer substrate 3 in proximity to the through-hole 4. The bonding pads 9 of the semiconductor chip 5 and bonding pads 8A of the first interposer substrate 3 are electrically connected by gold bonding wires 10. A larger number of connecting pads (electrodes) 8B that lead to the mother board 16 are formed on the lower surface of the first interposer substrate 3. These pads 8B have solder balls 11 disposed thereon.

A large number of bonding pads (electrodes) 12A are formed on the lower surface of the second interposer substrate 7 in proximity to the side wall of the through-hole 4. The bonding pads 9 of the semiconductor chip 5 and the bonding pads 12A of the second interposer substrate 7 are electrically connected by gold bonding wires 13. A large number of connecting pads (electrodes) 12B that lead to the mother board 16 are formed on the lower surface of the second interposer substrate 7, and these pads 1 2B have solder balls 11 disposed thereon.

The gap between the first interposer substrate 3 and the second interposer substrate 7 is sealed with a resin 15 to protect the gold bonding wires 10, 13. Thickness of the interposer substrate 3, 7 is preferably designed to be the same as the height of the solder ball 11, 14.

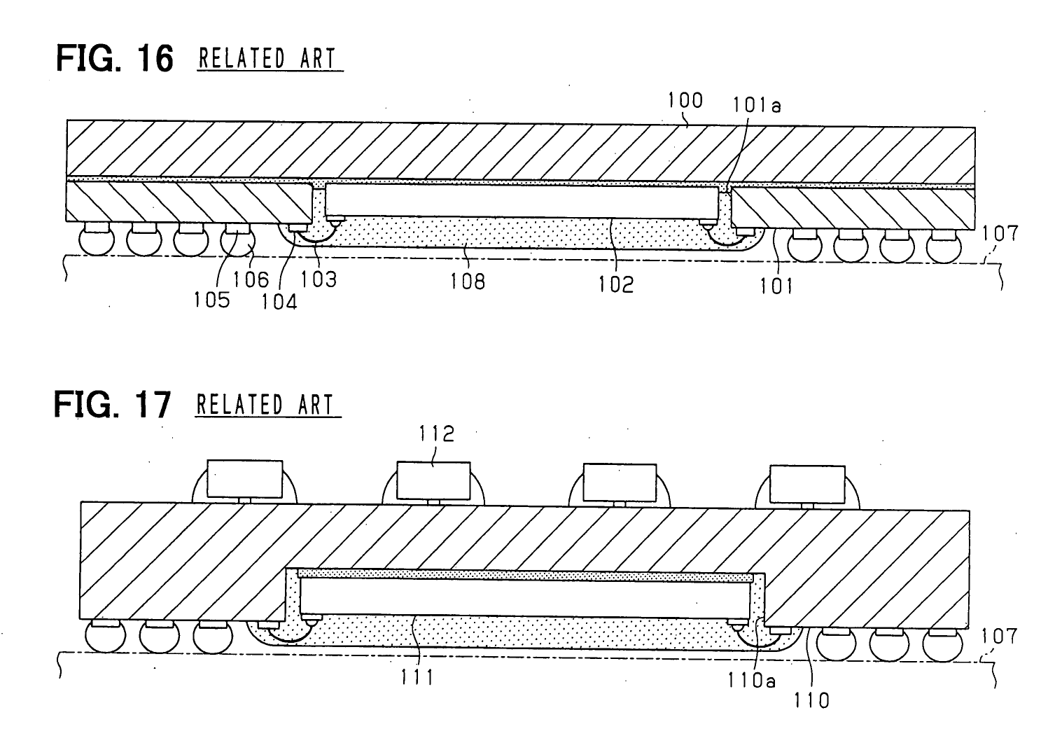

Referring briefly to the related art structure in FIG. 16, the package includes an interposer substrate 101 arranged around the semiconductor chip 102 that can accommodate electrodes electrically connected to the mother board (circuit board) 107 only in a periphery that is not covered by the semiconductor package. In comparison, the present embodiment includes connecting pads 12B (and the accompanying solder balls 14) arranged on a second interposer substrate 7 by placing the second interposer substrate 7 on the active side of the semiconductor chip 5 in the semiconductor package of the present embodiment. As a result, the number of pads (electrodes) 8B to be arranged on the interposer substrate 3 and the solder balls 11 can be decreased, and the semiconductor package can be thereby miniaturized. That is, the electrodes 12B that are electrically connected to the mother board 16 can be arranged on the second interposer substrate 7 that is placed on the active side of the semiconductor chip 5, and thus the semiconductor package can be miniaturized.

(Second Embodiment)

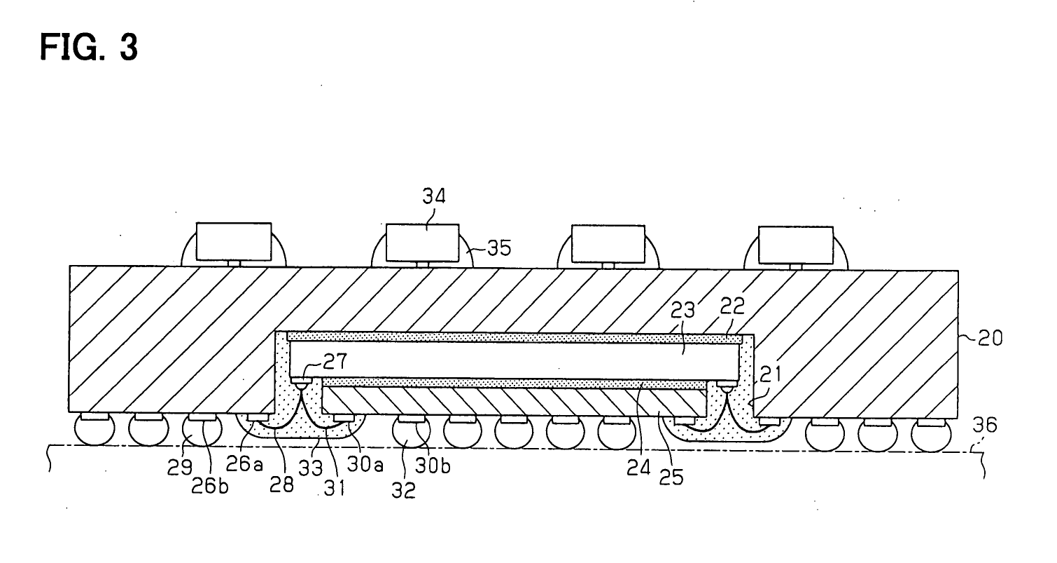

FIG. 3 shows a vertical section of the semiconductor package according to a third embodiment. The first interposer substrate 20 is rectangular in shape. A concave portion (cavity) 21 is formed in the center on one side (lower surface) of the first interposer substrate 20. A non-active side of the semiconductor chip 23 is fixed to the bottom of the concave portion 21 by an adhesive 22 inside of the concave portion 21 to thereby enclose the semiconductor chip 23 in the concave portion 21. One side of the second interposer substrate 25 is fixed to the active side (lower surface) of the semiconductor chip 23 by an adhesive 24 in the concave portion 21 of the first interposer substrate 20. In a broader sense, one side of the second interposer substrate 25 is fixed to the active side of the semiconductor chip 23. As the second interposer substrate 25 is smaller than the semiconductor chip 23, a large number of bonding pads (electrodes) 27 are formed in the lower surface of the semiconductor chip 23 where the surface is not covered by the second interposer substrate 25.

A large number of bonding pads (electrodes) 26A are formed on the lower surface of a first interposer substrate 20 in proximity to the concave portion 21. Bonding pads 27 on the semiconductor chip 23 and bonding pads 26A on the first interposer substrate 20 are electrically connected by gold bonding wires 28. A large number of connecting pads (electrodes) 26B that lead to a mother board 36 are formed on the lower surface of the first interposer substrate 20, and these pads 26B have solder balls 29 disposed thereon.

A large number of bonding pads (electrodes) 30A are formed on the lower surface of the second interposer substrate 25 in proximity to the side wall of the concave portion 21. The bonding pads 27 on the semiconductor chip 23 and the bonding pads 30A on the second interposer substrate 20 are electrically connected by gold bonding wires 31. A large number of connecting pads (electrodes) 30B that lead to the mother board 36 are formed on the lower surface of the second interposer substrate 25. These pads 30B have solder balls 32 disposed thereon.

The gap between the first interposer substrate 20 and the second interposer substrate 25 in the proximity of the side wall of the concave portion 21 is sealed with a resin 33 to protect the gold bonding wires 28, 31. Thickness of both the first interposer substrate 20 and the second interposer substrate 25 as well as the depth of the concave portion 21 are preferably designed to be the same as the height of the solder ball 29, 32.

Referring briefly to the related art structure in FIG. 17, the package includes an interposer substrate 110 arranged around the semiconductor chip 111 to accommodate electrodes that are electrically connected to the mother board 107 only in the periphery that is not covered by the semiconductor package. In comparison, the present embodiment includes connecting pads 30B (and the accompanying solder balls 32) that can be arranged on the second interposer substrate 25 by placing the second interposer substrate 25 on the active side of the semiconductor chip 23 in the semiconductor package. As a result, pads (electrodes) 26B to be arranged on the interposer substrate 26B and the solder balls 29 can be decreased in number, and thus the semiconductor package can be miniaturized. That is, the electrodes 30B that are electrically connected to the mother board 36 can be arranged on the second interposer substrate 25 that is placed on the active side of the semiconductor chip 23, and thus the semiconductor package can be miniaturized.

Further, an electronic component 34 is implemented by conductive material 35 such as solder or silver paste on the opposite side of the first interposer substrate 20 to the one side fixed to the semiconductor chip 23. When the electronic component 34 that used to be implemented on the mother board 36 is implemented on this side of the semiconductor package, the mother board 36 can be miniaturized.

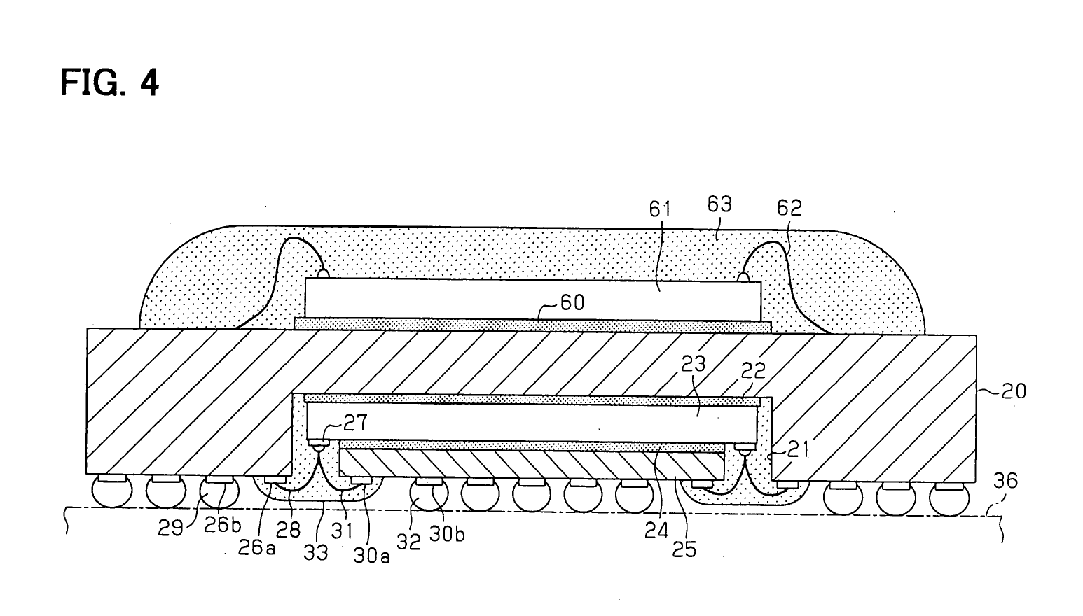

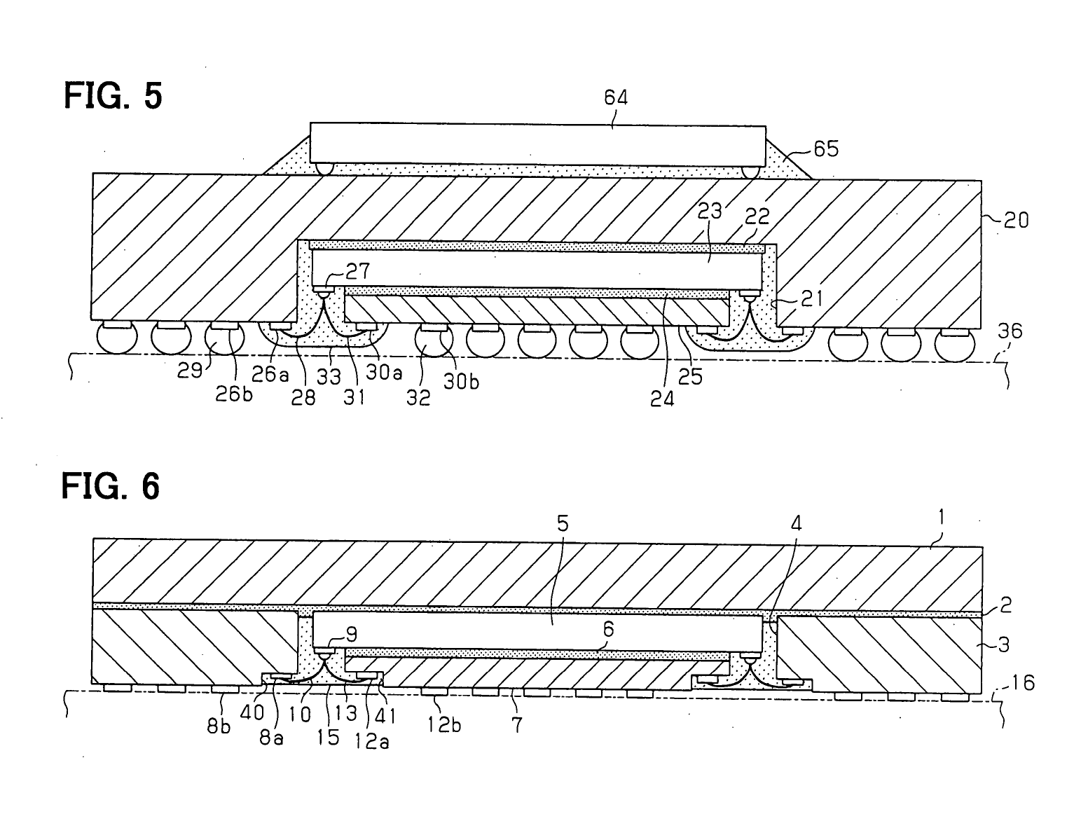

The electronic component 34 that is implemented on the interposer substrate 20 may be a passive part such as a resistor or condenser, or an active component such as a semiconductor chip or the like. Referring to FIGS. 4 and 5, the semiconductor chip may be implemented on the interposer substrate 20 by wire bonding or a flip-chip connection. In FIG. 4, the first interposer substrate 20 has a semiconductor chip 61 disposed on a side opposite to the side on which the semiconductor chip 23 is disposed. In detail, the semiconductor chip 61 is fixed by an adhesive 60 and is bonded by gold bonding wires 62 (electrically connected) at the same time to the first interposer substrate 20, and the semiconductor chip 61 and the gold bonding wires 62 are further molded by a resin 63.

In FIG. 5, a semiconductor chip 64 is implemented on a side on the first interposer substrate 20 different to the side on which the semiconductor chip 23 is disposed. In detail, the semiconductor chip 64 is fixed by a flip-chip connection to be electrically connected to the first interposer substrate 20, and a resin 65 is placed between the semiconductor chip 64 and the first interposer substrate 20.

In FIGS. 4 and 5, the mother board 36 can be miniaturized by implementing the semiconductor chips 61, 64 on the back of the semiconductor package instead of implementing them on the mother board 36.

(Third Embodiment)

Referring to the vertical sectional view of the semiconductor package in FIG. 6, a third embodiment will be discussed by focusing on differences with the first embodiment.

Step portions 40, 41 are formed on the interposer substrates 3, 7 to receive bonding pads (electrodes) 8A, 12A, which are connected to the semiconductor chip 5. That is, step portions 40, 41 are disposed on the side closer to the pad (electrode) 9 of the semiconductor chip 5 on the first and second interposer substrates 3, 7. The pads (electrodes) 8A, 12A to be bonded to the gold bonding wires 10, 13 are arranged on the step portions 40, 41.

The step portions 40, 41 enable a closer spacing between the bonding pads (electrodes) 12A and the bonding pads (electrodes) 12B to be connected to the mother board 16 by limiting overflow of the resin 15 that protects the gold bonding wires 10, 13, thereby resulting in a miniaturized semiconductor package. Moreover, the height of the resin 15 can be set under the surface level of the interposer substrates 3, 7, and solder balls are not needed to connect the bonding pads (electrodes) 12B to the mother board 16, resulting in a cutback of cost.

This structure can be adopted when the semiconductor chip 23 is placed in the cavity 21 of the interposer substrate 20 in the second embodiment.

(Fourth embodiment)

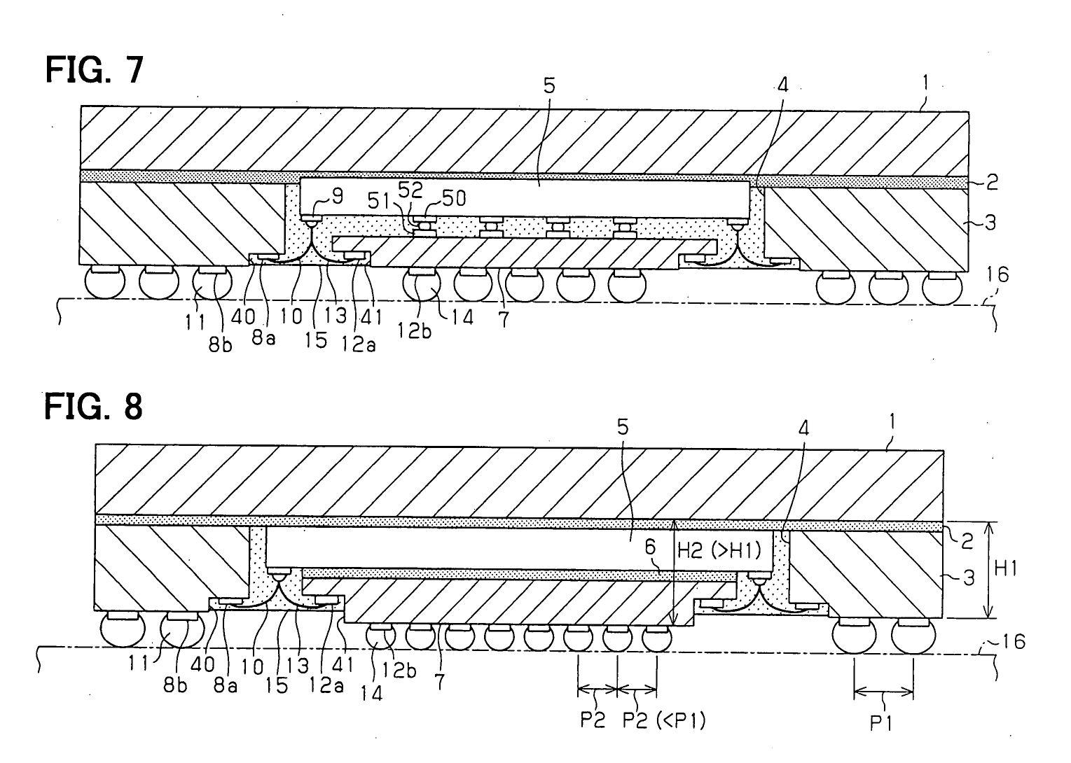

Next, the fourth embodiment is described by focusing on differences with the first embodiment. FIG. 7 shows a vertical section of the semiconductor package in the present embodiment.

The pads (electrodes) 50 are formed on the active side of the semiconductor chip 5. The pads (electrodes) 51 are formed on the upper face of the interposer substrate 7. The semiconductor chip 5 and the second interposer substrate 7 are connected in a flip-chip connection. Arranging pads (electrodes) 50 of the semiconductor chip 5 in the internal space in addition to the circumference of the semiconductor chip 5 can result in an effectively miniaturized semiconductor package.

This structure can be adopted when the semiconductor chip 23 is placed in the cavity 21 of the interposer substrate 20 in the second embodiment.

(Fifth embodiment)

Referring to FIG. 8, a fifth embodiment of the semiconductor package will be described by focusing on differences with the first embodiment. An interval P2 between the pads (electrodes) 12B to be connected to the mother board 16 of the second interposer substrate 7 is different from an interval P1 between the pads (electrodes) 8B to be connected to the mother board 16 of the first interposer substrate 3, and P2 is smaller than P1 (P2<P1)).

As mentioned above, decreasing the interval P2 between the electrodes on the second interposer substrate 7 leads to an increase in the number of electrodes on the second interposer substrate 7. Therefore, it decreases the number of electrodes on the first interposer substrate 3 and thus results in a miniaturized semiconductor package.

The interval P2 may be larger than P1 in this embodiment. Further, the height H2 of the surface that carries the pads (electrodes) 12B to be connected to the mother board 16 on the second interposer substrate 7 is different from the height H1 of the surface that carries the pads (electrodes) 8B to be connected to the mother board 16 on the first interposer substrate 3.

An electrode placement surface (under surface) of the interposer substrate 3, 7 is electrically and mechanically connected to the mother board 16 with conductive material such as solders, silver paste and the like. When the interval between the electrodes differs in scale, size of the electrodes also differs. A difference in size of the electrodes leads to a difference of conductive material used to connect the pads to the mother board 16. By varying the height H1, H2 of the interposer substrate 3, 7, the gap between the substrates can be adjusted by the amount of the conductive material.

Concretely, when an optimum size of the gap after a connection of two substrates is set to the radius size of the electrodes (size of pads), that is, the interval P1 of electrodes on the first interposer substrate 3 equals 0.8 mm and the size φ of the electrodes equals 0.45 mm, the interval P2 of electrodes on the second interposer substrate 7 equals 0.5 mm and the size φ of the electrodes equals 0.25 mm, the optimum value of the gap should be 0.255 mm on the first interposer substrate 3, and 0.125 mm on the second interposer substrate 7. Therefore, heights of the electrode placement H1, H2 on the interposer substrates 3, 7 are designed to fulfill the following condition. The condition is that the gap between the second interposer substrate 7 and the mother board 16 shall be decreased by 0.1 mm.

Accordingly, when the height of the electrode placements are the same on both of the interposer substrates 3, 7, a gap of a connection portion is determined based on the larger electrodes on the interposer substrates if two interposer substrates to be connected to the mother boards 16 have different electrodes sizes (amount of solder). As a result, when the first interposer substrate 3 has a larger electrodes size, the gap (distance) between the electrodes on the second interposer substrate 7 becomes larger than the optimum value. That is, the distance of the gap deviates from the optimum value based on the size of the electrodes and the amount of the solder, and this may deteriorate the reliability of connection. This situation can be avoided by changing the heights H1, H2 of both interposer substrates 3, 7.

As described in the first embodiment, the structure described above may be adopted in the same situation as the second embodiment in which the semiconductor chip 23 is in the cavity 21 of the interposer substrate 20.

In the first to fifth embodiments, the material for the first and second interposer substrate may differ.

FIG. 7 shows the situation in detail. The mother board 16 and the semiconductor package are connected by the conductive material such as solder and the like. However, the difference of the linear expansion coefficient of the mother board 16 and the semiconductor package causes stress at connection points. Repeated expansion results in the breakage of connection points and thus malfunction. This kind of thermal stress caused by the difference of linear expansion coefficient increases proportionally to the distance from the center of the electrodes area. Therefore, the material for the first interposer substrate 3 has to be chosen from among the one with similar linear expansion coefficient as for the mother board 16. Moreover, although the second interposer substrate 7 has a limitation in size based on the size of the semiconductor chip 5, the semiconductor package can be further miniaturized if electrodes were disposed on the second interposer substrate 7. Thus, the second interposer substrate 7 uses a special substrate that can accommodate a high density circuit. By carefully choosing the material for the substrates, the semiconductor package can satisfy size and cost requirements.

Further, when the second interposer substrate 7 has a flip-chip connection with the semiconductor 5, the second interposer substrate 7 uses a substrate with similar linear expansion value as the semiconductor chip 5 (=3˜4 ppm/° C.)

In concrete, when the mother board 16 is made of glass epoxy resin substrate (linear expansion coefficient=15 ppm/° C.), the first interposer substrate 3 should also be made of the same material as the glass epoxy resin substrate. The second interposer substrate 7 is then made of a high density and low linear expansion coefficient (=7 ppm/° C.) multi-layered ceramic substrate. Consequently, high connection reliability with the mother board 16, high flip-chip connection reliability with the semiconductor chip 5, and high density implementation of the second interposer substrate 7 are all realized at the same time.

(Sixth embodiment)

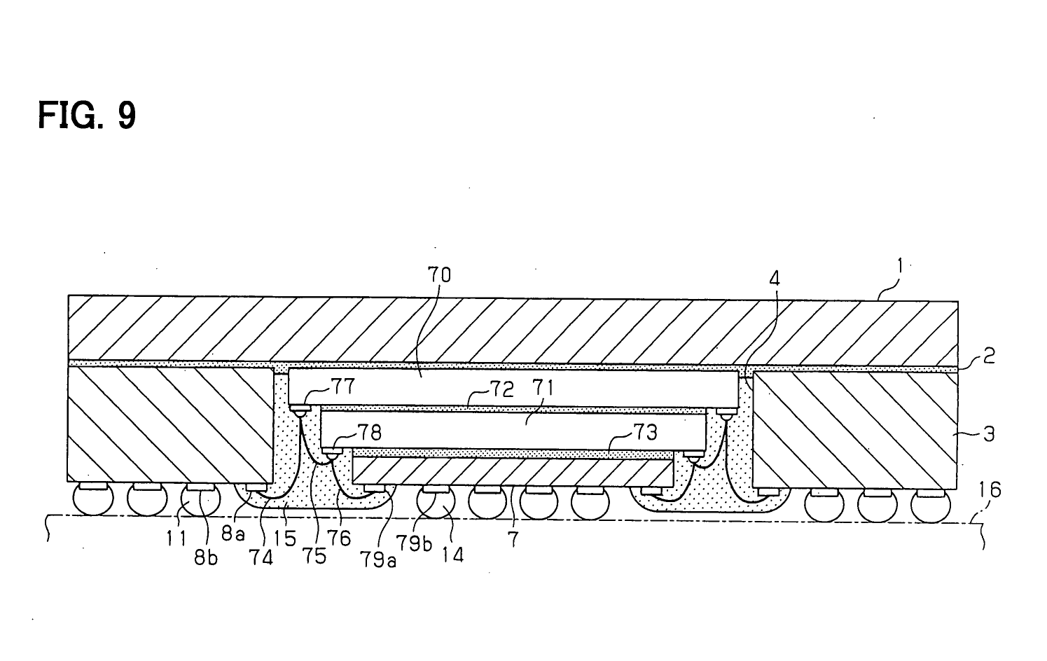

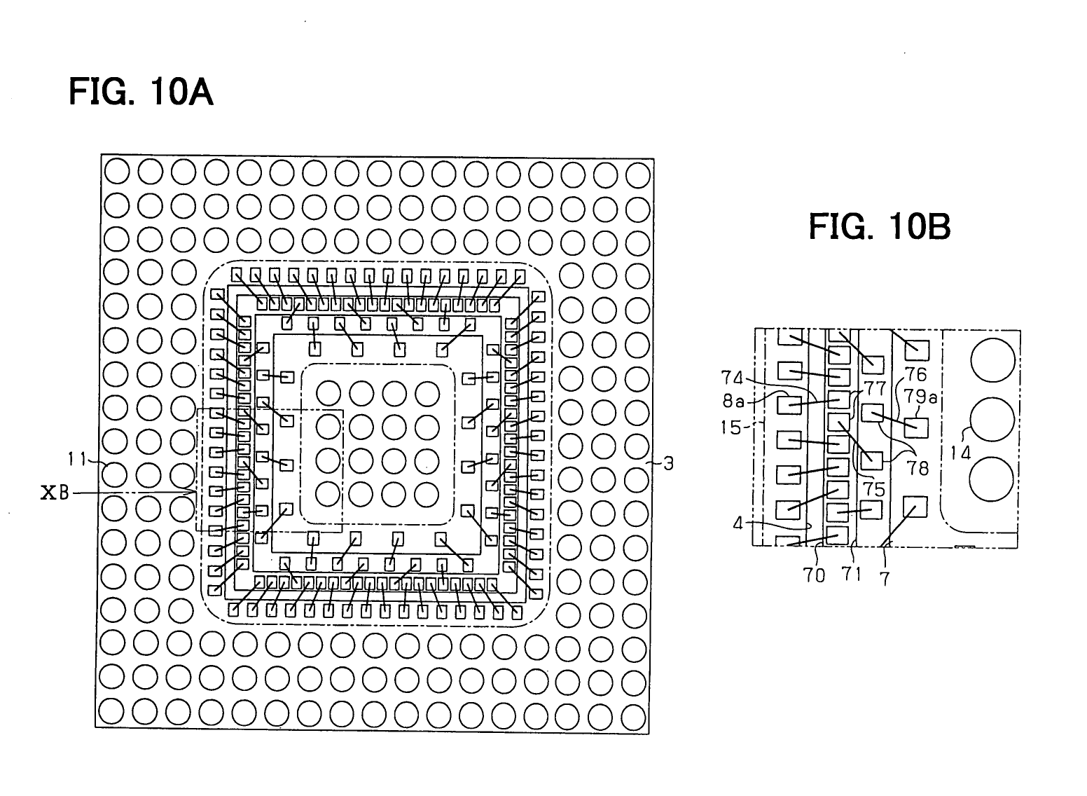

Referring to FIGS. 9-10, a sixth embodiment will be described by focusing on differences with the first embodiment. FIG. 9 shows a vertical section of the present embodiment, that substitutes the first embodiment. FIG. 10 shows a lower surface (the surface that opposes the mother board 16 in the FIG. 9) of the semiconductor package that substitutes the second embodiment.

In the first embodiment, as shown in FIGS. 1 and 2, the non-active side of the semiconductor chip 5 is fixed to one side (lower surface) of the heat sink 1 by an adhesive 2, and enclosed in the through-hole 4 of the first interposer substrate 3. However, in the sixth embodiment as shown in FIG. 9, the package includes multiple semiconductor chips 70, 71 in a stacked structure in which the active side of chip 70 opposes a non-active side of chip 71. More precisely, the non-active side of the semiconductor chip 70 is fixed to the heat sink 1 with an adhesive 2 in the through-hole 4, and the semiconductor chip 71 is fixed onto the semiconductor chip 70 with an adhesive 72. Further, the second interposer substrate 7 is fixed to the active side of the semiconductor chip 71 with an adhesive 73. The chip 71 is smaller than the chip 70, and a large number of pads (electrodes) 77 are formed in the area (periphery) that is not covered by the chip 71 on the active side (lower side) of the chip 70. Furthermore, the second interposer substrate 7 is smaller than the chip 71, and a large number of pads (electrodes) 78 are formed in the area (periphery) that is not covered by the second interposer substrate 7 on the active side of the chip 71.

On one side of the second interposer substrate 7, pads (electrodes) 79A are formed on the outer periphery, and pads (electrodes) 79B to be connected to the mother board 16 are formed just inside of the periphery.

The pads (electrodes) 8A on the first interposer substrate 3 and the pads 77 on the semiconductor chip 70 are electrically connected by gold bonding wires 74. The pads 77 on the semiconductor chip 70 and the pads 78 on the semiconductor chip 71 are electrically connected by gold bonding wires 75. The pads 78 on the semiconductor chip 71 and the pads 79A on the second interposer substrate 7 are electrically connected by gold bonding wires 76. Further, the pads 77 on the semiconductor chip 70 and the pads 79A on the second interposer substrate 7 may be electrically connected by gold bonding wires. The pads 78 on the semiconductor chip 71 and pads 8A on the first interposer substrate 3 may also be electrically connected by gold bonding wires. In short, as a wiring structure, at least one of the chips 70, 71 are connected to the first and second interposer substrates. Generally, the chip 70 and the first interposer substrate 3, the other chip 71 and the second interposer substrate 7, are electrically connected by gold bonding wires 74, 76 in the stacked structure.

The pads (electrodes) 8A, 77, 78, 79A with the gold bonding wires 74, 75, 76 are sealed by the resin 15. The other conditions are the same as the first embodiment. Therefore, FIGS. 9, 10 have the same numerals as FIGS. 1, 2 and the description of the numerals is omitted.

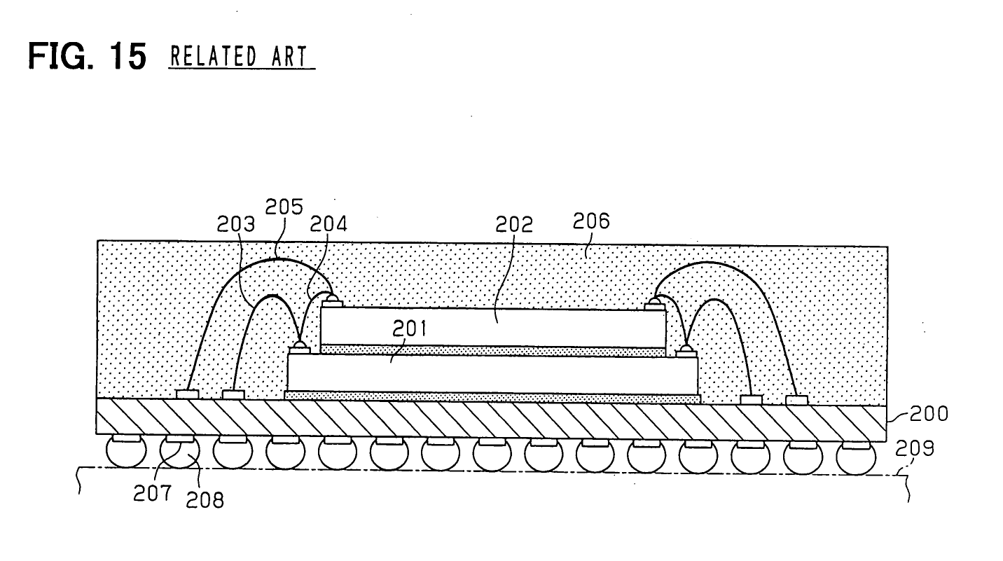

FIG. 15 is an example for comparison. The present embodiment shown in FIG. 9 and FIGS. 15, 16 will be compared.

In FIG. 15, a first semiconductor chip 201 is mounted on an interposer substrate and a second semiconductor chip 202 is mounted on the active side of the first semiconductor chip 201. In addition, the interposer substrate 200 and each semiconductor chip 201, 202 are electrically connected to each other by gold bonding wires 203, 204, 205. Further, on the lower surface (back side) of the interposer substrate 200, electrodes 207 are connected to a mother board 209 by bumps 208. Further, on the upper side of the interposer substrate 200, the gold bonding wires 203, 204, 205 and the active side of the semiconductor chip 201, 202 are covered by a resin 206 (plastic molding). In the structure shown in FIG. 15, the semiconductor chips 201, 202 have low heat dissipation efficiency because of the plastic molding by resin 206. Also, as shown in FIG. 16, a heat sink 100 improves heat dissipation efficiency, but poses a problem in terms of miniaturization.

In FIG. 9, the package has an improved heat dissipation efficiency when multiple chips 70, 71 are layered in a stacked structure compared to the one shown in FIG. 15, and also has an improvement in terms of miniaturization.

The stacked structures of layered multiple chips are described as follows.

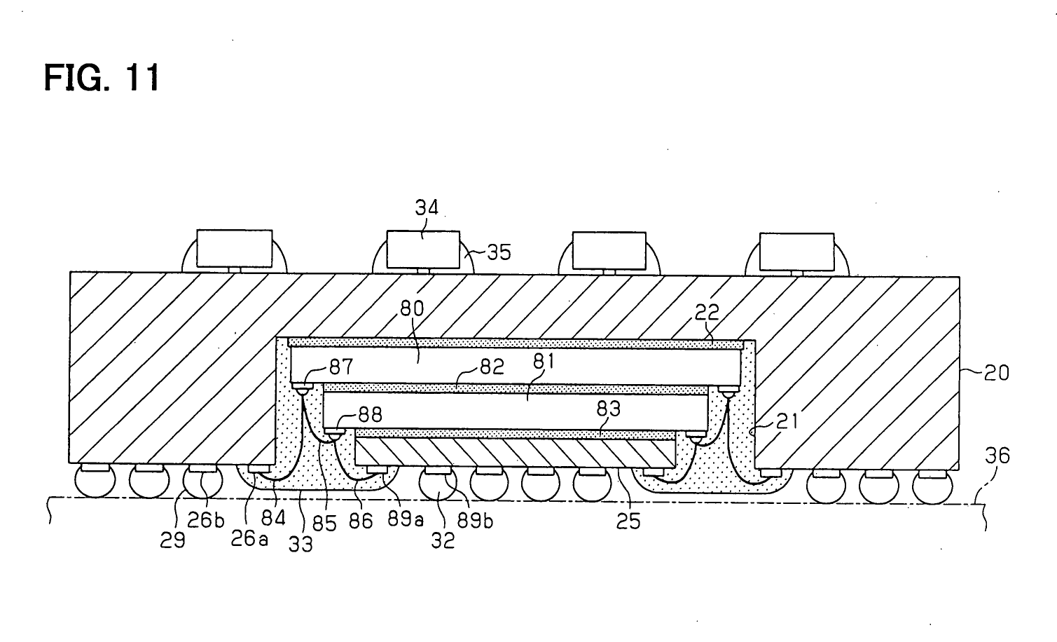

A structure that substitutes the one in FIG. 3 in the second embodiment is shown in FIG. 11. In FIG. 11, the package has a layered stacked structure of multiple chips 80, 81, and in the stacked structure, the active side of the chip 80 opposes non-active side of the chip 81. More precisely, the non-active side of the semiconductor chip 80 is fixed onto the bottom of a cavity 21 with an adhesive 22 in the cavity 21 on the first interposer substrate 20, and the semiconductor chip 81 is fixed onto the semiconductor chip 80 with an adhesive 82. The semiconductor chip 81 is fixed to the semiconductor chip 80 by an adhesive 82. A second interposer substrate 25 is fixed to an active side of the semiconductor chip 81 with an adhesive 83. The chip 81 is smaller than the chip 80, and a large number of pads (electrodes) 87 are formed in the area (periphery) that is not covered by the chip 81 on the active side (lower side) of the chip 80. Furthermore, the second interposer substrate 25 is smaller than the chip 81, and a large number of pads (electrodes) 88 are formed in the area (periphery) that is not covered by the second interposer substrate 25 on the active side of the chip 81.

The pads (electrodes) 87 on the semiconductor chip 80 and pads 26 on the first interposer substrate 20 are electrically connected by gold bonding wires 84. The pads 87 on the semiconductor chip 80 and the pads 88 on the semiconductor chip 81 are electrically connected by gold bonding wires 85. The pads 88 on the semiconductor chip 81 and the pads 89A on the second interposer substrate 25 are electrically connected by gold bonding wires 86. Further, pads 87 on the semiconductor chip 80 and pads 89A on the second interposer substrate 25 may be electrically connected by gold bonding wires. Alternatively, the pads 88 on the semiconductor chip 81 and pads 26A on the first interposer substrate 25 may also be electrically connected by gold bonding wires. In short, as a wiring structure, at least one of the chips 80 and 81 are connected to the first and second interposer substrates, or more precisely, the chip 80 and the first interposer substrate 20, and, the other chip 81 and the second interposer substrate 25, may be electrically connected by gold bonding wires 84, 86 in the stacked structure.

The pads (electrodes) 89B to be used for a connection to the mother board 36 are formed on the same surface as the pads 89A on the second interposer substrate 25, where pads 89B are arranged inside of the pads 89A. Further, the gold bonding wires 84, 85, 86 and pads 26A, 87, 88, 89A are sealed with a resin 33. Further, the electric components 34 are mounted on the side opposite to the one with the semiconductor chips 80, 81 on the first interposer substrate 20 by using conductive material 35 such as solder, silver paste and the like. The electric components 34 are the passive components such as resistors, condensers and the like. As shown in FIG. 4, 5, active components such as semiconductor chip 61, 64, may be mounted on the other side of the one with the semiconductor chip 80, 81 on the first interposer substrate 20. In this case, the components are mounted by using wire bonding and/or flip-chip connection technology.

As described above, the structure shown in FIG. 11 is favorable for miniaturization of the package in which multiple chips 80, 81 are layered in the stacked structure.

In addition, the other conditions are the same as the one in the second embodiment. Therefore, FIG. 11 has the same numerals as FIG. 3 and the description of the numerals is omitted.

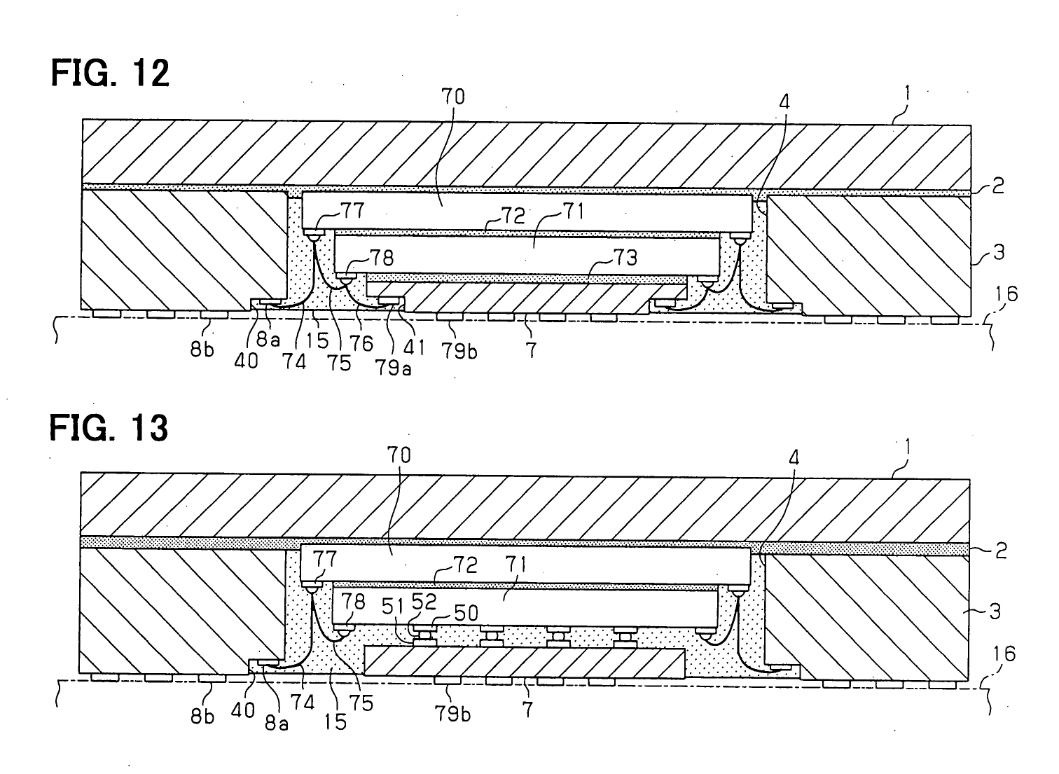

A variation of the structure shown in FIG. 9 is proposed in FIG. 12 (an alternative for the structure shown in FIG. 6).

As shown in FIG. 12, step portions 40, 41 are disposed on the side close to the pads (electrodes) 77, 78 of the semiconductor chips 70, 71 on the first and second interposer substrates 3, 7, and pads (electrodes) 8A, 79A to be bonded to gold bonding wires 74, 76 are arranged on the step portions 40, 41. This structure enables a closer spacing between bonding pads (electrodes) 79A and bonding pads (electrodes) 79B to be connected to the mother board 16 by limiting overflow of the resin 15 that protects gold bonding wires 74, 75, 76 with step portions 40, 41, resulting in a miniaturized semiconductor package. Moreover, the height of the resin 15 can be set under the surface level of the interposer substrates 3, 7, and the bonding pads (electrodes) 79B can be disposed without solder balls in order to be connected to the mother board 16, resulting in a cutback of cost. Step portions 40, 41 shown in FIG. 12 may also be formed in the structure shown in FIG. 11.

A variation of the structure shown in FIG. 12 is proposed in FIG. 13 (an alternative for the structure shown in FIG. 7).

In FIG. 13, pads (electrodes) 51 are formed on the interposer substrate 7 for an electric connection to the chip 71, and the pads 51 reside on the other surface of the substrate that carries pads 79B to be connected to the mother board 16 on one side. The pads (electrodes) 50 are formed on the active side of the chip 71 for a connection to the second interposer substrate 7. The pads (electrodes) 51 are connected to the pads 50 by using the bumps 52. That is, the chip 71 and the interposer substrate 7 are fixed to each other by bumps 52 in the flip-chip connection. The structure shown in FIG. 13 in which the chip and the second interposer substrate 7 are connected by bumps may be applicable to the structures shown in FIG. 9 and FIG. 11. Further, the second interposer substrate 7 may be electrically connected to the chips 70, 71 by using gold bonding wires in addition to the bump connection. Furthermore, in the structure shown in FIG.9, FIG. 11, and FIG. 12, the chips may be connected to the second interposer substrate by using bumps.

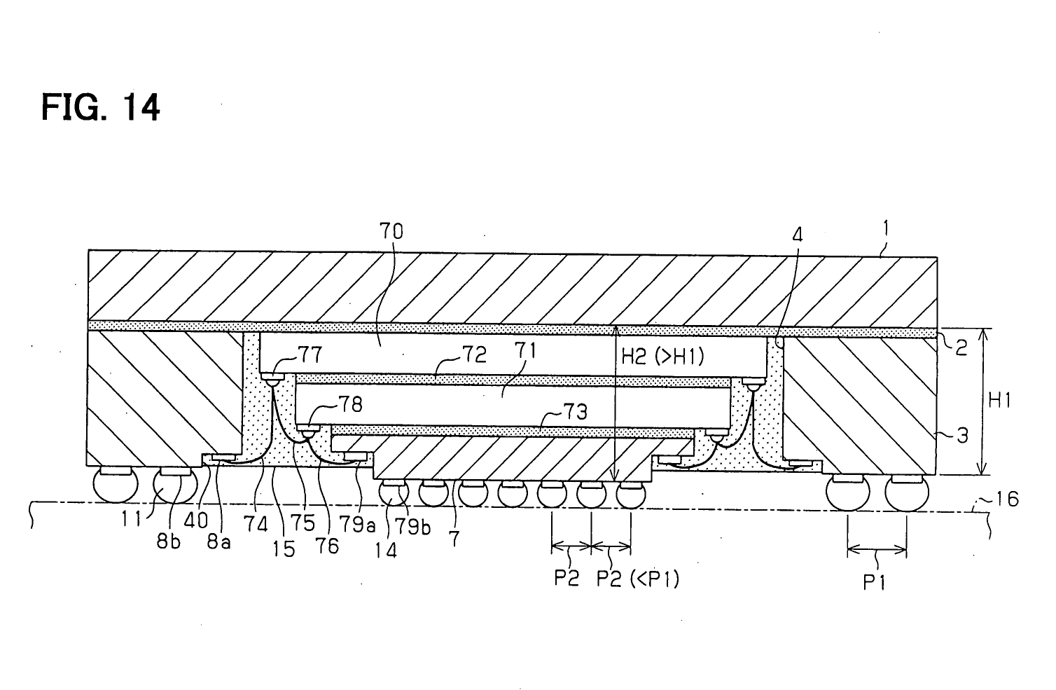

A variation of the structure shown in FIG. 12 is proposed in FIG. 14 (an alternative for the structure shown in FIG. 8). In FIG. 14, the interval P2 between the pads (electrodes) 79B that are formed on the second interposer substrate 7 for a connection to the mother board 16 is smaller than the interval P1 between the pads (electrodes) 8B that are formed on the first interposer substrate 3 for a connection to the mother board 16 (In a broader sense, the interval P2 differs from the interval P1). By decreasing the interval P2 of the pads 79B on the second interposer substrate 7, the number of the pads 79B to be formed on the second interposer substrate 7, and thus the number of the pads 8B on the first interposer substrate 3 can be decreased, resulting in a miniaturized semiconductor package. The pads (electrodes) 8B, 79B, for the connection of the interposer substrate 3, 7, to the mother board 16 carry solder balls 11, 14, and the solder balls 14 on the second interposer substrate 7 are smaller in diameter than the solder balls 11 on the first interposer substrate 3. In order to adjust the top points of the solder balls to be level, the under surface of the first interposer substrate 3 is displaced from the under surface of the second interposer substrate 7 (H2>H1). That is, the height H2 of a surface on the second interposer substrate 7 that carries pads (electrodes) 79B for a connection to the mother board 16 is different from the height H1 of a surface of the first interposer substrate 3 that carries pads (electrodes) 8B for a connection to the mother board 16. The structure shown in FIG. 14, in which the interval P2 differs from the interval P1, and the height H2 differs from the height H1, may be applicable to the structure shown in FIG. 11.

The other conditions are the same as the embodiment shown in FIG. 5. Therefore, FIG. 14 has the same numerals as FIG. 8 and the description of the numerals is omitted.

Each interposer substrate in a stacked chip structure may be made of different materials. Detail (material of the substrates and the like) is aforementioned in the fifth embodiment, and the description is not repeated here.

In the structure where chips are stacked, a stack of two layers of chips is shown. However, the chips may be stacked in three or more layers. When the number of chip-layers is increased, it is more favorable in terms of miniaturization of semiconductor package.

The description of the invention is merely exemplary in nature and, thus, variations that do not depart from the gist of the invention are intended to be within the scope of the invention. Such variations are not to be regarded as a departure from the spirit and scope of the invention.

Therefore, the present disclosure concerns a semiconductor package including a first interposer substrate 3 fixed to a side portion of a heat sink 1, wherein the first interposer substrate 3 includes a through-hole 4, a semiconductor chip 5 fixed to the side portion of the heat sink 1 and a second interposer substrate 7 fixed to an active side of the semiconductor chip 5. The semiconductor chip 5 is electrically connected to the first interposer substrate 3 and the second interposer substrate 7 by gold bonding wire 13.

The package may include semiconductor chips having a stacked layer structure. An active side of the semiconductor chip 70 opposes a non-active side of another semiconductor chip 71 to form a stacked layer structure. One of the semiconductor chips 70 of the stacked layer structure and the first interposer substrate 3 are electrically connected by gold bonding wire 74, 76, and the other of the semiconductor chips 71 in the stacked layer structure and the second interposer substrate 7 are electrically connected by gold bonding wire 74, 76.

The semiconductor package may also include a first interposer substrate 20 having a concave portion 21, a semiconductor chip 23 enclosed within the first interposer substrate 20, wherein a non-active side of the semiconductor chip 23 is fixed to the concave portion 21 and a second interposer substrate 25 fixed to an active side of the semiconductor chip 23, wherein the first interposer substrate 20 and the semiconductor chip 23 are electrically connected by gold bonding wire 28, and the semiconductor chip 23 and the second interposer substrate 25 are electrically connected by gold bonding wire 31. An active side of the semiconductor chip 80 opposes a non-active side of another semiconductor chip 81 to form a stacked layer structure and one of the semiconductor chips 80 of the stacked layer structure and the first interposer substrate 20 are electrically connected by gold bonding wire 84, 86. The other of the semiconductor chips 81 in the stacked layer structure and the second interposer substrate 25 are electrically connected by gold bonding wire 84, 86. An electronic component 34 may be disposed on a surface of the first interposer substrate 20 opposite to the concave portion 21. A semiconductor chip may be disposed on the opposite side of the surface of the first interposer substrate 20 to that on which the semiconductor chip 23 closed within the first interposer substrate 20 is disposed. Also, step portions 40, 41 may be disposed on an electrode side 9 of the first and second interposer substrates 3, 7, wherein electrodes 8A, 12A to be bonded to the gold bonding wires 10, 13 are dispose on the step portions.

The semiconductor chip 5 and the second interposer substrate 7 are in a flip-chip type of connection with interfacing bumps 52. An interval (P2) of the electrodes 12B disposed on the second interposer substrate 7 for the connection to the mother board 16 is different from an interval (P1) of the electrodes 8B disposed on the first interposer substrate 3 for the connection to the mother board.

A height (H2) of the surface on the second interposer substrate 7 that carries the electrodes 12B to be connected to the mother board 16 is different from the height (H1) of the surface on the first interposer substrate 3 that carries the electrodes 8B to be connected to the mother board 16. Preferably, a material used for the first interposer substrate 3 and a material used for the second interposer substrate 7 is different.

In the above described embodiments, gold bonding wire is used. However, the bonding wire is not limited to gold. Other materials, such as aluminum or copper, may also be used to implement the bonding wire.

1. A semiconductor package comprising:
a first interposer substrate that includes a through-hole and is fixed to a side portion of a heat sink;
a semiconductor chip fixed to the side portion of the heat sink; and
a second interposer substrate fixed to an active side of the semiconductor chip, wherein the first interposer substrate and the semiconductor chip are electrically connected by bonding wire, wherein the semiconductor chip and the second interposer substrate are electrically connected by bonding wire.

2. The semiconductor package according to claim 1, wherein:
an active side of the semiconductor chip opposes a non-active side of another semiconductor chip to form a stacked layer structure of semiconductor chips; and
one of the semiconductor chips of the stacked layer structure and the first interposer substrate are electrically connected by the bonding wire and the other of the semiconductor chips in the stacked layer structure and the second interposer substrate are electrically connected by the bonding wire.

3. A semiconductor package comprising:
a first interposer substrate having a concave portion;
a semiconductor chip enclosed within the first interposer substrate, wherein a non-active side of the semiconductor chip is fixed to the concave portion; and
a second interposer substrate fixed to an active side of the semiconductor chip,
wherein the first interposer substrate and the semiconductor chip are electrically connected by bonding wire, and the semiconductor chip and the second interposer substrate are electrically connected by bonding wire.

4. The semiconductor package according to claim 3, wherein:
the active side of the semiconductor chip opposes the non-active side of another semiconductor chip to form a stacked layer structure; and
one of the semiconductor chips of the stacked layer structure and the first interposer substrate are electrically connected by the bonding wire and the other of the semiconductor chips in the stacked layer structure and the second interposer substrate are electrically connected by the bonding wire.

5. The semiconductor package according to claim 3, wherein an electronic component is disposed on a surface of the first interposer substrate opposite to the concave portion.

6. The semiconductor package according to claim 3, further comprising another semiconductor chip disposed on the opposite side of the surface of the first interposer substrate to that on which the semiconductor chip enclosed within the first interposer substrate is disposed.

7. The semiconductor package according to claim 3, wherein step portions are disposed on an electrode side of the first and second interposer substrates, wherein electrodes to be bonded to the bonding wires are disposed on the step portions.

8. The semiconductor package according to claim 3, wherein the semiconductor chip and the second interposer substrate are in a flip-chip type of connection with interfacing bumps.

9. The semiconductor package according to claim 3, wherein an interval of the electrodes disposed on the second interposer substrate for the connection to the mother board is different from an interval of the electrodes disposed on the first interposer substrate for the connection to the mother board.

10. The semiconductor package according to claim 3, wherein a height of the surface on the second interposer substrate that carries the electrodes to be connected to the mother board is different from a height of the surface on the first interposer substrate that carries the electrodes to be connected to the mother board.

11. The semiconductor package according to claim 3, wherein a material used for the first interposer substrate and a material used for the second interposer substrate is different.

12. The semiconductor package according to claim 1, wherein step portions are disposed on an electrode side of the first and second interposer substrates, wherein electrodes to be bonded to the bonding wires are disposed on the step portions.

13. The semiconductor package according to claim 1, wherein the semiconductor chip and the second interposer substrate are in a flip-chip type of connection with interfacing bumps.

14. The semiconductor package according to claim 1, wherein an interval of the electrodes disposed on the second interposer substrate for the connection to the mother board is different from an interval of the electrodes disposed on the first interposer substrate for the connection to the mother board.

15. The semiconductor package according to claim 1, wherein a height of the surface on the second interposer substrate that carries the electrodes to be connected to the mother board is different from a height of the surface on the first interposer substrate that carries the electrodes to be connected to the mother board.

16. The semiconductor package according to claim 1, wherein a material used for the first interposer substrate and a material used for the second interposer substrate is different.
